(19) United States
(12) Patent Application Publication
(10) Pub. No.: US 2005/0243430 A1
(43) Pub. Date: Nov. 3, 2005

(54) Apparatus for controlled transmittance of solar radiation

(75) Inventor: Christopher Cuttle, Auckland (NZ)

Correspondence Address: DARBY & DARBY P.C., P. O. BOX 5257, NEW YORK, NY, 10150-5257, US

(73) Assignee: Auckland Uniservices Limited, Auckland (NZ)

(21) Appl. No.: 11/101,147

(22) Filed: Apr. 6, 2005

(30) Foreign Application Priority Data
Apr. 6, 2004 (NZ) NZ 532191

(51) Int. Cl. H01L 27/14; H01L 31/00; G02B 27/00; G02B 5/00; G02B 7/00

(52) U.S. Cl. 359/613; 359/894

(57) ABSTRACT

Apparatus that may be used as a skylight or window for allowing natural light to enter a building has light impeding regions (104) arranged in a planar configuration above one or more other light impeding regions (100) arranged in a lower plane so that the regions are spaced apart. The arrangement allows selective transmittance of natural light so that light incident from directly overhead is largely impeded, but light from other angles is largely unimpeded. This reduces the variation in light levels within building structures, reducing thermal loading problems. The apparatus may also be orientation independent.

### BACKGROUND OF THE INVENTION

This invention relates to apparatus for controlling transmittance of solar radiation, and is directed particularly, but not solely, to controlling the passage of light through windows such as skylights.

Controlling the transmittance of natural light into structures, particularly commercial buildings such as warehouses shops and factories can have significant benefits. Natural light is usually more aesthetically pleasing to occupants of such buildings than artificial light. Also, allowing natural light into such buildings can reduce the amount of artificial light that is required, and therefore reduce energy usage.

Accordingly, many buildings, including residential dwellings, have skylights in the roof to bring daylight into the building. These usually take the form of clear windows in the roof which transmit a large percentage of incident light into the building.

An advantage of skylights over vertical windows is that skylights can provide even distributions of daylight illumination over large floor areas, The main problem with skylights is that when the sun is at high altitude (i.e. substantially in the middle of the day), they admit high levels of solar heat gain. As these thermal gains coincide with times of high ambient temperatures, they may cause unacceptable cooling loads. Designers respond by opting for restricted skylight areas, which limits the duration of useful daylight illumination.

### OBJECT OF THE INVENTION

It is an object of the present invention to provide apparatus for controlled transmittance of solar radiation which will at least go some way to overcoming disadvantages of known constructions, or to at least provide a useful alternative.

Further objects of the invention will become apparent from the following description.

### SUMMARY OF THE INVENTION

Accordingly in one aspect the invention consists in apparatus for controlled transmittance of solar radiation, the apparatus including a plurality of first solar radiation impeding regions substantially arranged in a first planar configuration, at least one second radiation impeding region substantially arranged in a second planar configuration, the second plane being substantially parallel to the first plane but spaced therefrom in a direction perpendicular to both planes, and the second radiation impeding region being a substantial complement of the first radiation impeding regions, whereby the passage of solar radiation through the apparatus may be impeded by the first or the second radiation impeding regions such that the transmittance of solar radiation by the apparatus is directionally selective.

The first radiation impeding regions can be arranged in a pattern, and the first and second radiation impeding regions define a solar radiation transmittance region therebetween.

In the preferred embodiment the region of radiation transmittance comprises at least one wall provided between each of the first radiation impeding regions and the second radiation impeding region.

The at least one wall is inclined at an angle relative to a line perpendicular to the first and second planes, so that in the preferred embodiment it comprises a frustum of a cone.

The passage of solar radiation through the apparatus may be impeded by the first or the second radiation impeding regions and the degree of radiation impedance presented by the apparatus is dependent on the angle of incidence of the radiation on the apparatus.

The light impeding regions are preferably substantial barriers to passage of natural light, but may also comprise translucent or opaque regions.

The light impeding regions may further include a pattern of variable light impedance.

Preferably the apparatus includes insulating means. In the preferred form the insulating means are provided between the first and second surfaces. The insulating means preferably comprise one or more air gaps and most preferably a plurality of closed cells.

Preferably the light impeding regions are printed or adhered to each surface. However, the regions may be provided by other methods, for example, etching, or applied during a manufacturing process, for example, moulding or extruding.

The apparatus is suitable for use as a skylight or a window pane or panel.

For the purposes of this specification and claims, the word “comprise” and variations such as “comprising” and “comprises” is to be interpreted in an inclusive sense unless the context clearly requires the contrary.

### BRIEF DRAWING DESCRIPTION

FIG. 1: is a diagrammatic cross section of a structure including a skylight;

FIG. 2: Is a diagrammatic cross section of one example of apparatus according to the invention;

FIG. 3: is a partial plan view of a first surface of the apparatus of FIG. 2;

FIG. 4: is a partial plan view of a second surface of the apparatus of FIG. 2;

FIG. 5: is a diagrammatic plan view of the surfaces of FIGS. 3 and 4 superimposed one above the other;

FIG. 6: is a partial plan view of a further example of the first surface of the apparatus of FIG. 2;

FIG. 7: is a partial plan view of a further example of a second surface of the apparatus of FIG. 2;

FIG. 8: is a plan view of the surfaces of FIGS. 6 and 7 superimposed one above the other;

FIG. 9: is a partial plan view of a further example of the first surface of the apparatus of FIG. 2;

FIG. 10: is a partial plan view of a further example of a second surface of the apparatus of FIG. 2;

FIG. 11: is a plan view of the surfaces of FIGS. 9 and 10 superimposed one above the other;

FIG. 12: is a diagrammatic cross section of a further example of apparatus according to the invention;

FIG. 13: is a diagrammatic cross section of a further example of apparatus according to the invention;

FIG. 14: is a diagrammatic partial cross section of an embodiment of the invention;

FIG. 15: is a partial diagrammatic cross section of an alternative form of apparatus according to the invention;

FIG. 16: is an illustrative graph of light intensity on the vertical axis plotted against time on the horizontal axis during daylight hours of one day;

FIG. 17: is a perspective view of apparatus according to another embodiment of the invention;

FIG. 18: is an elevation in cross section through a part of the apparatus of FIG. 17;

FIG. 19: is a graph of relative direct radiant admission (vertical axis) against time of day (horizontal axis)

FIG. 20: is a graph of relative illuminance (vertical axis) against time of day (horizontal axis);

FIG. 21: is a graph of temperature in degrees celcius (vertical axis) against time of day (horizontal axis).

### DESCRIPTION OF THE BEST MODES FOR PERFORMING THE INVENTION

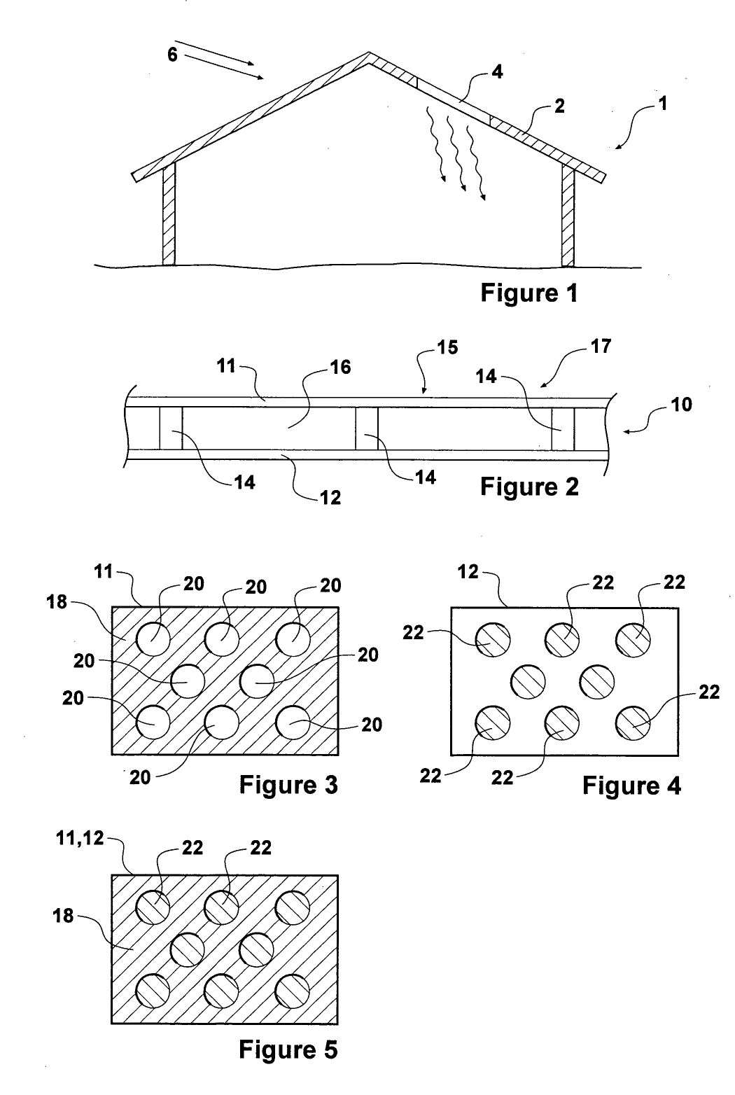

Referring to FIG. 1, a typical skylight installation is illustrated diagrammatically in which a building structure generally referenced 1 has a roof 2 which has a skylight 4 therein through which solar radiation may enter. As shown in FIG. 1, the skylight will often be provided on the side of the building which is unlikely to receive direct sunlight. For example, in the northern hemisphere the skylight may be provided on the northern side of the building and in the southern hemisphere the skylight may be provided on the southern side of the building. In this way, light 6 which is incident on the roof of the building is less likely to be directly incident upon occupants of the building and less likely to cause thermal problems through excess heat entering the building. However, it is not always possible to place a skylight in a position where the skylight is subject only to diffuse light.

Turning now to FIG. 2, a first embodiment of apparatus which may be used to provide a skylight in accordance with the invention is shown diagrammatically in cross section. In the embodiment shown in FIG. 2, the apparatus 10 has first layer of a substantially planar material 11 and a second layer of similar material 12. The two layers of sheet material are separated by spacers 14 to space the sheets apart in a direction perpendicular to the plane of each sheet, leaving an air gap 16 between sheets 11 and 12.

The sheets 11 and 12 are each provided with at least one solar radiational light impeding region which is arranged in a pattern. Referring to FIG. 3, a first pattern for the first sheet 11 is shown. Here the light impeding region is providing a pattern which leaves circles 20 through which light may freely pass. This pattern can be created in a variety of ways. In one example, the sheet 14 is made from a substantially light impervious material or possibly a reflective material, and the pattern is formed by drilling apertures through the material which form circles 20 that allow light to pass. Another possibility is to provide the sheet 11 in a form of a transparent material and print would adhere, or etch, or otherwise apply a light impeding pattern comprising area 18 which leaves transparent regions 20, in a preferred form these regions 20 are approximately 5 mm-20 mm in diameter and the space between the sheets 11 and 12 is of a similar dimension, selected to allow desired directionally selective transmittance.

Turning now to FIG. 4, the second sheet 12 is shown. In this sheet, the light impeding region comprises a plurality of regions 22 substantially in the form of circles. This is most easily formed by providing sheet 12 as a sheet of transparent material and then printing, adhering, etching or otherwise providing, regions 22 in the decided localities. The impeding regions 22 may be reflective.

Turning now to FIG. 5, the sheets 11 and 12 have been laid one above the other as shown in FIG. 2, from which it can be seen that the light impeding regions 18 and 22 are the substantial complement of each other, so that when light is directly incident on the construction shown in FIG. 2 (i.e. from the direction of arrow 15 in FIG. 2), this light cannot pass through the construction 10. Therefore, if the construction 10 is provided in the form of a skylight panel in a building roof which is substantially horizontal, then light from directly overhead sun will not pass directly into the building. However, light which is incident on the construction 10 from other angles, for example from the direction of arrow 17 in FIG. 2, may pass partially through the apparatus. This will be described further below. Those skilled in the art will appreciate that a variety of different constructions may be employed, and that the patterns illustrated in FIGS. 3 to 5 is simply one example of a way of putting the invention into effect. The invention may also be used to allow a certain amount of direct light (for example light in the direction arrow 15 in FIG. 2) to pass through the construction if desired. Therefore, for example, although the complementary pattern illustrated and described with reference to FIGS. 3 to 5 is one where there is a substantially exact correspondence between regions 20 and 22, in another embodiment regions 22 are instead of slightly smaller diameter than regions 20, to therefore allow a desired amount of high altitude direct light to still pass through the apparatus. Regions 22 could also be a slightly larger diameter to prevent transmittance of high altitude light from the direction of arrow 15 in FIG. 2 and similar high altitude directions.

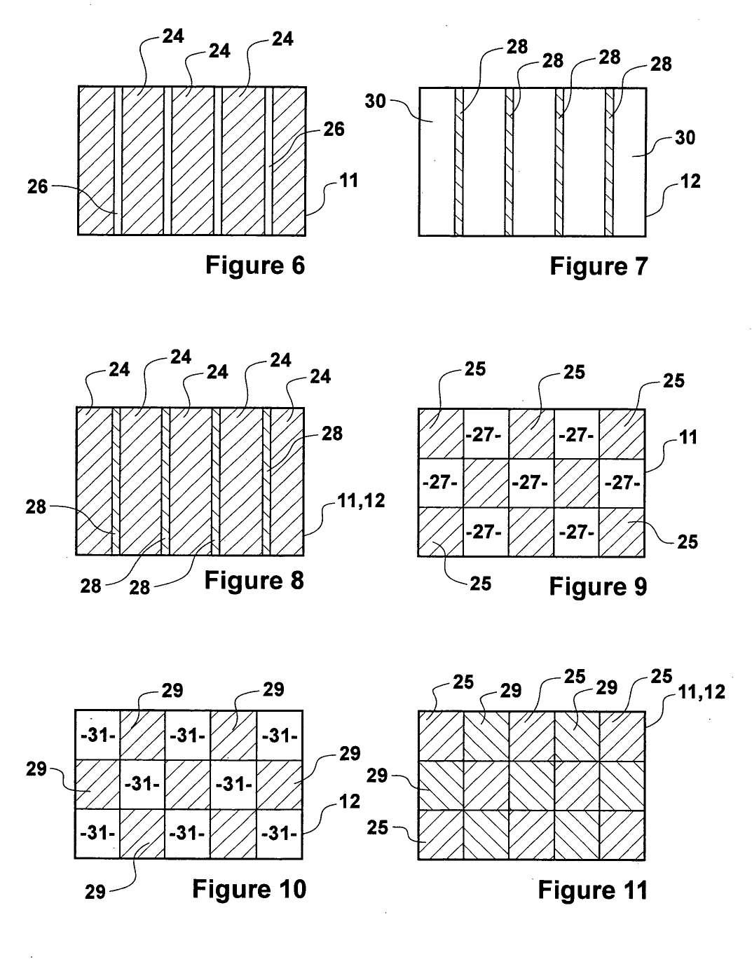

Turning now to FIGS. 6 to 8, an alternative arrangement of light impeding regions is illustrated. In FIG. 6, the light impeding regions are provided by areas 24 on the first sheet 11 with regions 26 allowing a free passage of light. In FIG. 7, regions 28 impede passage of light and regions 30 allow passage of light. When the two materials are superimposed, as shown in FIG. 8, direct light (again such as that shown by arrow 15 in FIG. 2) is substantially impeded. A disadvantage with the construction shown in FIGS. 6 to 8 is that the regions of light impedance are not multi-directional, so that a certain direction of installation may be required. Thus the regions of light impedance need to be aligned in a north/south direction in use to be most effective. This will become apparent from the further description below.

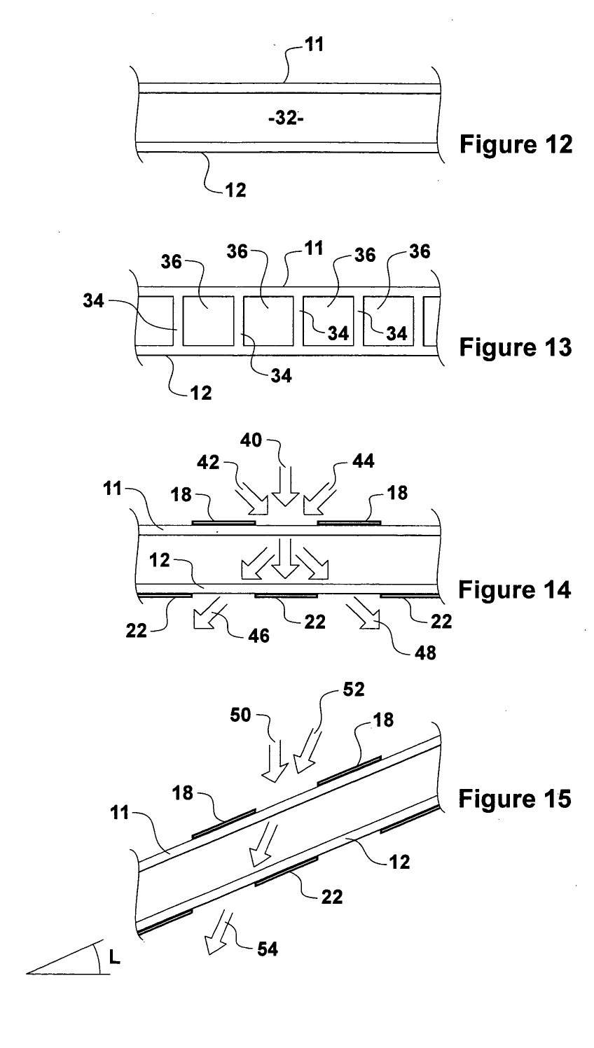

In FIGS. 9 and 10, another arrangement of light impeding regions is shown. In FIG. 9, the light impeding regions are provided by areas 25 on the first sheet 11 with regions 27 allowing free passage of light. In FIG. 10, regions 29 impede transmittance of light and regions 31 allow transmittance of light. When the two sheets are superimposed, as shown in FIG. 11, direct light is substantially impeded. This construction has the advantage, like the construction of FIGS. 3-5 (and unlike the construction of FIGS. 5-8) that it is effective when installed in any orientation i.e. it is orientation independent. In FIG. 12, an alternative construction is shown whereby a laminated construction is adopted with sheets 11 and 12 being located (for example by being adhered or otherwise laminated) with a central transparent region 32. Of course, as another alternative, the apparatus could comprise a single solid sheet of material, for example plastics or glass, with the regions printed, or etched, or adhered to the upper and lower surfaces. Also, it will be appreciated that in a laminated construction shown in FIG. 12, and with the construction shown in FIG. 2, the surfaces of sheets 11 and 12 on which the patterns are provided could be the exterior surfaces of each sheet, or interior surfaces of each sheet or intermediate surfaces of each sheet, or a combination of these.

In FIG. 13, a further preferred embodiment is illustrated in which integral supports 34 are provided leaving cells 36 which may comprise air spaces for example in the form of closed calls which thereby provide an insulating function. Providing insulation is a significant advantage as it allows the construction not only to control the amount of light entering a building structure to thereby provide some temperature control, but it also allows the temperature of the environment within the building to be more effectively controlled relative to that outside. Accordingly, energy efficiency is greatly enhanced.

Turning now to FIG. 14 operation of the embodiments of the preceding figures will be described. In FIG. 14, a diagrammatic partial cross section of a construction such as that of FIG. 2 or FIG. 12 is illustrated. The upper region of impedance 18 is shown as if it was a layer adhered or printed on an upper surface of layer 11 and regions 22 are shown as if they were adhered or printed to a lower surface of sheet 12. Considering firstly direct light incident on a construction on a perpendicular direction as shown by arrow 40, it will be seen that although this light passes through first sheet 11, it is prevented by a region 22 from passing through the construction. Considering light incident from a lesser angle, such as that shown by arrows 42 and 44, there are regions that allow light to pass as indicated by arrows 46 and 48. Furthermore, it will be seen that as the angle reduces toward a direction parallel to the plane of the apparatus, so too does the amount of light which is allowed to pass until a relatively high angle of incidence is reached (the angle of incidence being typically defined relative to the surface normal). Those skilled in the art will appreciate that the pattern described with reference to FIGS. 3 to 5 is one which is independent of the direction of orientation of the construction relative to the path of the sun through the sky, unlike that disclosed with reference to FIGS. 6 to 8.

It will also be appreciated that the arrangement of the complementary patterns on the first and second surfaces may be arranged to allow for the manner in which the window or skylight is to be installed. For example in FIG. 15, the patterns are arranged for a skylight in a roof which may be angled at an angle L which during the middle of the day experiences direct overhead sunlight in a direction 50. As can be send from FIG. 15 the arrangement of the pattern substantially prevents this direct sunlight from being experienced in the building. However, as the sun moves across the sky, for example so that light is incident in a direction 52, then sunlight are allowed to pass as indicated by arrow 54. Those skilled in the art will also appreciate that a variety of other patterns, or relative arrangement of patterns, that are substantially complementary, may be provided to take account of varying local conditions such as distance form the equator, orientation of the roof or other features of geometry.

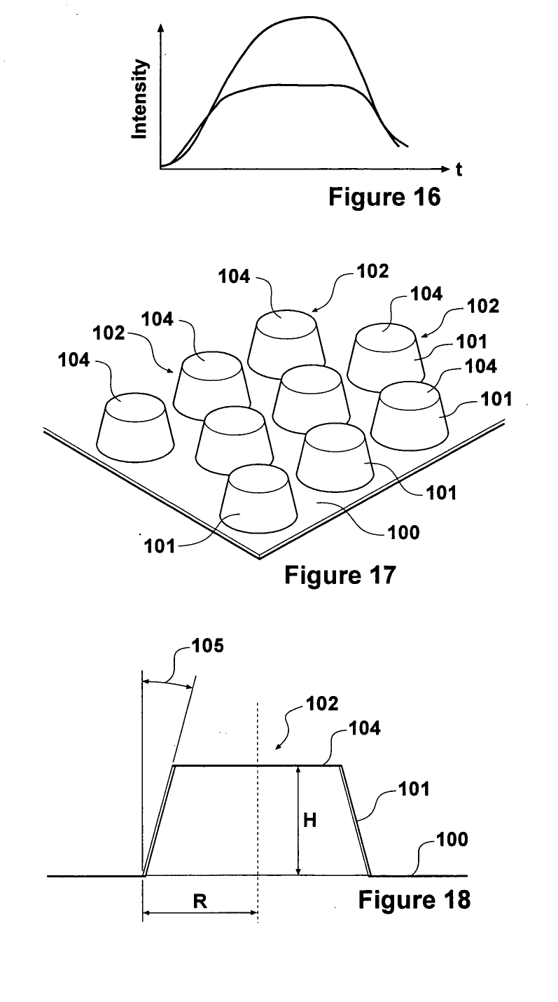

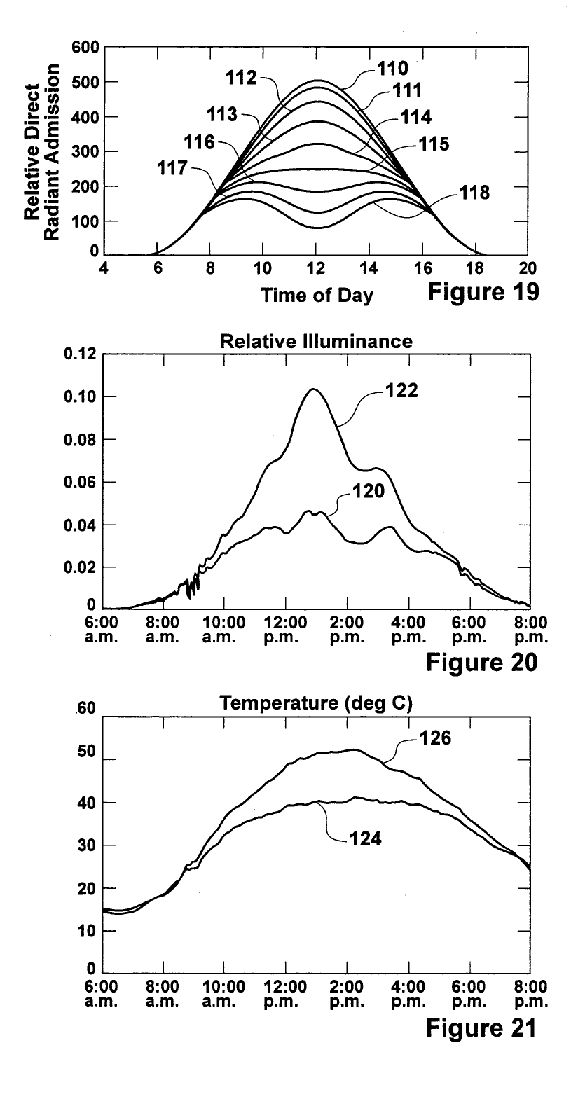

The benefits provided by the construction are illustrated by the graph shown in FIG. 16. As shown in that figure, locus 60 is a plot of intensity of received light against time during daylight hours which may be incident upon a skylight for example. If the skylight has no directional sensitivity, then this general locus will also represent the amount of sunlight which enters the building. Therefore there is a high illumination during the middle of the day and a consequential rise in temperature. Locus 62 generally represents the intensity of light received within a building having a skylight according to the present invention. As can be seen, use is made of the natural light at the beginning and end of the day to assist with illumination, but light during the middle of the day is attenuated or reduced to provide a lesser variation of overall light intensity within the structure which results in more pleasing natural light and a reduced effect on internal building temperature.

The invention has been described with reference to the surfaces 11 and 12 having light impeding regions, but it will be understood that those regions also provide light a complementary region or regions of light transmittance. Thus the invention may also be described with reference to light transmitting regions or a combination of light impeding and light transmitting regions.

A further embodiment of the invention is illustrated in FIGS. 17 and 18. A matter that affects the performance of the embodiments described above is that at low solar altitudes (i.e. at angles of solar incidence which are approaching a position parallel to the plane of the apparatus), there are reflection losses. The embodiment of FIGS. 17 and 18 has been found to overcome this problem by reducing the angle of incidence to the radiation transmitting material (i.e. transparent material) for low altitude sunlight.

Referring to FIG. 17, it can be seen that the apparatus comprises plurality of “domes” generally referenced 102. The upper portion of each dome 102 provides a solar radiation impeding region 104. As can be seen, there are a plurality of domes, preferably arranged in a pattern, and the regions 104 are arranged in a substantial planar configuration. The planar arrangement is spaced from a further solar radiation impeding region 100 which is also arranged in a general planar configuration. The separation between the regions 104 and region 100 is achieved by walls 101 of each dome, each wall being substantially transparent (i.e. solar radiation transmitting). It will appreciated that, although the shape of each dome 102 is illustrated as being circular (and therefore providing a desired orientation independant arrangement), other shapes may be used including hexagonal or octagonal shapes, for example.

For greater clarity, the cross sections through one of the domes 102 of FIG. 17 is shown in FIG. 18 as can be seen, the wall 101 has a tilt angle 105, so that some direct radiation at angles of high solar altitude i.e. angles almost perpendicular to the general plane of the structure described will pass through the transmitting wall material 101. Thus the wall 101 in the embodiment illustrated has the form of a frustum of a cone.

A computer program was developed specifically to examine the effect of the tilt angle 105. The model assumed that the height H (see FIG. 18) was equal to the radius R (refer FIG. 18) and a refractive index value of 1.5 was assumed for the sloping transparent sides 101. FIG. 19 shows the results in which the loci 110 to 118 represent a range of angle 105 from 45° to 5° respectively. From this study a tilt angle of 105 of 15° was chosen as the optimum overall for providing the longest duration of relatively constant diurnal radiant emission.

Test data has confirmed the efficacy of the embodiment illustrated in FIGS. 17 and 18. An enclosure of approximately 1 m×1 m×1 m was constructed having a ceiling of a similar construction to that shown in FIG. 17, with eight dome structures. Each dome 102 was approximately 95 mm in diameter, and had a tilt angle 105 of 15°. A “control” enclosure had a ceiling with eight light emitting apertures of the same diameter as the base of each of the domes on the experimental structure. Referring to FIG. 19, a graph of relative illuminance against time for the interior of the experimental structure is represented by locus 120, while the control provided locus 122, As can be seen, the peak illuminance during the early afternoon period of the day is substantially reduced while illuminance in early morning and late afternoon is preserved. Similarly, in FIG. 21, a locus 124 demonstrates temperature with respect to time for the interior of the experimental structure and that of the control is represented by locus 126. The dome structure has significantly reduced temperature variation caused by solar radiation.

The test results for the embodiment illustrated in FIG. 17 or 18 demonstrate satisfactorily the characteristics of both directionally selective transmittance and orientation independence. The tilt angle of the dome sides i.e. of wall 101 appears to satisfy the ideal condition.

It will be seen that, although the embodiment shown in FIG. 17 and FIG. 18 is designed for a window or skylight which is in a horizontal position, sloped windows or roofs could be accommodated by manufacturing the material with the domes 102 offset by the slope angle. In this way, the orientation independence of the skylight material could be maintained.

From the foregoing it will be seen that the present invention has significant advantages, particularly in that the transmittance of the skylight or window material is directionally selective, in that the proportion of low altitude sunlight that is transmitted is greater than the proportion of high altitude sunlight. This enables larger skylights to be used, thereby providing increased duration of useful daylight illumination, without incurring unacceptably high solar heat gains in the mid-portion of the day. This selectivity may also be orientation independent. The apparatus may be constructed from unitary sheets of moulded or rolled material, such as plastics or similar materials. The light impeding regions may be designed to totally or partially impede solar radiation and can be provided form separate materials, or provided by etching or printing processes. Furthermore, the light impeding regions may be created during or post-manufacture.

The scope of the invention is not limited to the specific embodiments described above but also includes those modifications, additions, improvements, equivalents and substitutions which a person skilled in the art would appreciate are within the scope of the invention as defined in the appended claims.

1. Apparatus for controlled transmittance of solar radiation, the apparatus including a plurality of first solar radiation impeding regions substantially arranged in a first planar configuration, at least one second radiation impeding region substantially arranged in a second planar configuration, the second plane being substantially parallel to the first plane but spaced therefrom in a direction perpendicular to both planes, and the second radiation impeding region being a substantial complement of the first radiation impeding regions, whereby the passage of solar radiation through the apparatus may be impeded by the first or the second radiation impeding regions such that the transmittance of solar radiation by the apparatus is directionally selective.

2. Apparatus as claimed in claim 1 wherein the first radiation impeding regions are arranged in a pattern.

3. Apparatus as claimed in claim 1 wherein the first and second radiation impeding regions define a solar radiation transmittance region therebetween.

4. Apparatus as claimed in claim 3 wherein the region of radiation transmittance comprises at least one wall provided between each of the first radiation impeding regions and the second radiation impeding region.

5. Apparatus as claimed in claim 4 wherein the at least one wall is inclined at an angle relative to a line perpendicular to the first and second planes.

6. Apparatus as claimed in claim 4 wherein the at least one wall comprises a frustum of a cone.

7. Apparatus as claimed in claim 1 where the passage of solar radiation through the apparatus may be impeded by the first or the second radiation impeding regions and the degree of radiation impedance presented by the apparatus is dependent on the angle of incidence of the radiation on the apparatus.

8. A skylight including the apparatus of claim 1.

9. A window pane or panel comprising the apparatus of claim 1.

10. Apparatus as claimed in claim 2 wherein the first and second radiation impeding regions define a solar radiation transmittance region there between.

11. Apparatus as claimed in claim 10 wherein the region of radiation transmittance comprises at least one wall provided between each of the first radiation impeding regions and the second radiation impeding region.

12. Apparatus as claimed in claim 11 wherein the at least one wall is inclined at an angle relative to a line perpendicular to the first and second planes.

13. Apparatus as claimed in claim 11 wherein the at least one wall comprises a frustum of a cone.
